(19) United States
(12) Patent Application Publication
(10) Pub. No.: US 2026/0058611 A1
(43) Pub. Date: Feb. 26, 2026

(54) VOLTAGE AND CURRENT PROTECTION FOR AN AMPLIFIER

(71) Applicant: QUALCOMM Incorporated, San Diego, CA (US)

(72) Inventors: Bonhoon KOO, San Diego, CA (US); Smarjeet SHARMA, Arnhem (NL); Jianguo YAO, Londonderry, NH (US); Marc Gerald DICICCO, Dunstable, MA (US); Frederic CARREZ, Boxborough, MA (US); Changhyuk CHO, San Diego, CA (US); Md Naimul HASAN, San Diego, CA (US); SURAJ PRAKASH, San Diego, CA (US); Kun WANG, Sunnyvale, CA (US); Francesco CARRARA, San Diego, CA (US); Scott DAVENPORT, Merrimack, NH (US); Antonino SCUDERI, San Diego, CA (US)

(21) Appl. No.: 18/813,760

(22) Filed: Aug. 23, 2024

(51) Int. Cl. H03F 1/52; H03F 3/24; H03G 3/30

(52) U.S. Cl. CPC H03F 1/52; H03F 3/245; H03G 3/3042; H03F 2200/426; H03F 2200/462

(57) ABSTRACT

Certain aspects of the present disclosure generally relate to electronic circuits and, more particularly, to techniques and apparatus for signal amplification. One example apparatus generally includes: a current sensor configured to sense a current associated with an amplifier; and a voltage sensor configured to sense a voltage associated with the amplifier. The apparatus may also include a logic circuit configured to: detect a first over-current condition associated with the amplifier based on the current; detect a first over-voltage condition associated with the amplifier based on the voltage; and adjust an amplification gain to yield a first adjusted gain level for an input signal based on detection of the first over-current condition and the first over-voltage condition, wherein the amplifier is configured to amplify the input signal based on the first adjusted gain level.

### TECHNICAL FIELD

Certain aspects of the present disclosure generally relate to electronic circuits and, more particularly, to techniques and apparatus for signal amplification.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, 5G New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations or access points that can support communication for a number of mobile stations. A mobile station (MS) or access terminal may communicate with a base station (BS) or access point via a downlink and an uplink. The downlink (or forward link) refers to the communication link from the base station or access point to the mobile station or access terminal, and the uplink (or reverse link) refers to the communication link from the mobile station or access terminal to the base station or access point. A base station or access point may transmit data and control information on the downlink to the mobile station or access terminal. The base station or access point may also receive data and control information on the uplink from the mobile station or access terminal. The base station (or access point) and/or mobile station (or access terminal) may include a power amplifier (PA) for signal amplification.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards an apparatus for signal amplification. The apparatus generally includes: a current sensor configured to sense a current associated with an amplifier; a voltage sensor configured to sense a voltage associated with the amplifier; and a logic circuit configured to: detect a first over-current condition associated with the amplifier based on the current; detect a first over-voltage condition associated with the amplifier based on the voltage; and adjust an amplification gain to yield a first adjusted gain level for an input signal based on detection of the first over-current condition and the first over-voltage condition, wherein the amplifier is configured to amplify the input signal based on the first adjusted gain level.

Certain aspects of the present disclosure are directed towards an apparatus for signal amplification. The apparatus generally includes: an amplifier; a current sensor coupled to the amplifier; a voltage sensor coupled to the amplifier; a first comparator having an input coupled to an output of the current sensor; a second comparator having an input coupled to an output of the voltage sensor; an AND gate having inputs coupled to outputs of the first comparator and the second comparator; and a controller having an input coupled to an output of the AND gate and an output coupled to a circuit associated with the amplifier.

Certain aspects of the present disclosure are directed towards a method for signal amplification. The method generally includes: detecting a first over-current condition associated with an amplifier; detecting a first over-voltage condition associated with the amplifier; adjusting an amplification gain to yield a first adjusted gain level for an input signal based on the detection of the first over-current condition and the first over-voltage condition; and amplifying, via the amplifier, the input signal based on the first adjusted gain level.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) or access point (AP) and user equipment (UE), in which aspects of the present disclosure may be practiced.

FIG. 3 is a block diagram of an example radio frequency (RF) transceiver, in which aspects of the present disclosure may be practiced.

FIG. 4 illustrates an example radio frequency front end (RFFE) including voltage and current sensing, in accordance with certain aspects of the present disclosure.

FIG. 5A is a graph illustrating voltage and current consumption of an amplifier during low-stress conditions.

FIG. 5B illustrates is a graph illustrating voltage and current consumption of an amplifier during high-stress conditions.

FIG. 6 illustrates example combination logic and an example amplifier configuration controller, in accordance with certain aspects of the present disclosure.

FIG. 7 illustrates a combination logic processing trigger signals associated with different thresholds, in accordance with certain aspects of the present disclosure.

FIG. 8 is a graph illustrating voltage and current consumption of an amplifier during high-stress conditions with over-power protection, in accordance with certain aspects of the present disclosure.

FIG. 9 is a flow diagram illustrating example operations for signal amplification, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards apparatus and techniques for over-voltage and over-current protection. In some aspects, to protect a radio frequency front end (RFFE) in high-stress conditions, a power amplifier (PA) gain may be adjusted (e.g., by increasing input attenuation or decreasing bias current to the PA) in response to detection of both an over-voltage condition and an over-current condition. In this manner, lower voltage and current thresholds may be used in high-stress conditions to detect the over-voltage and over-current conditions to protect the RFFE. To protect the RFFE in low-stress conditions, the PA gain may be adjusted in response to the detection of an over-voltage condition or an over-current condition. To facilitate proper PA operations (e.g., allowing the PA to generate signals spanning current and voltage ranges per specifications) while protecting the RFFE in low-stress conditions, higher voltage and current thresholds may be used to detect the over-voltage and over-current conditions for protection in low-stress conditions, as described in more detail herein. Certain aspects provide for increased protection of RFFE components. For example, RFFE components may be protected in both low-stress conditions and high-stress conditions. The RFFE components may be protected against over-voltage, over-current, and over-power conditions, as described in more detail herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration. ” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

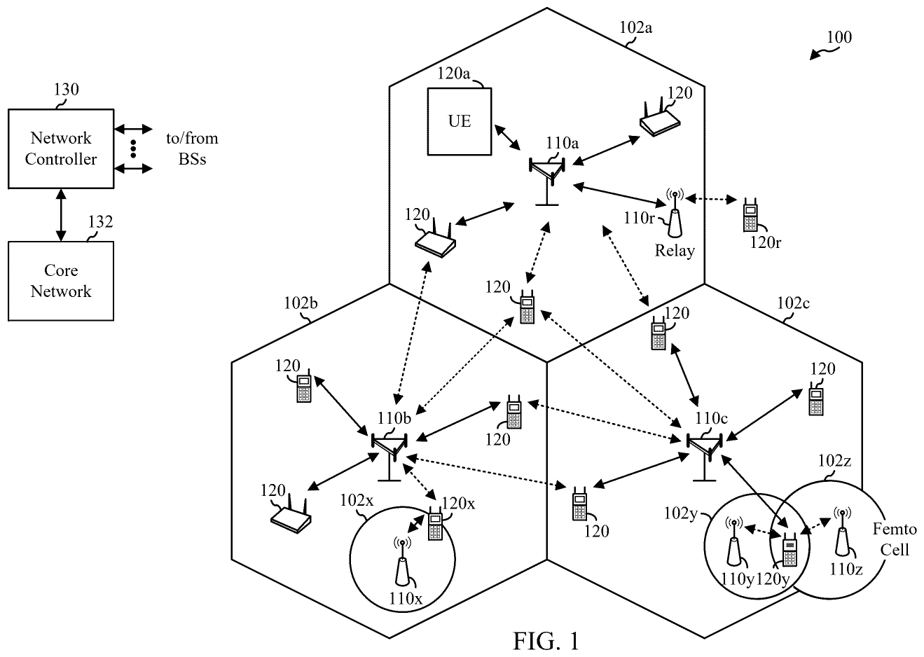

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as “relays” or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nᵤ UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

The UE 120 and/or 110 may be implemented with one or more amplifiers with over-current protection (OCP) and over-voltage protection (OVP), as described in more detail herein.

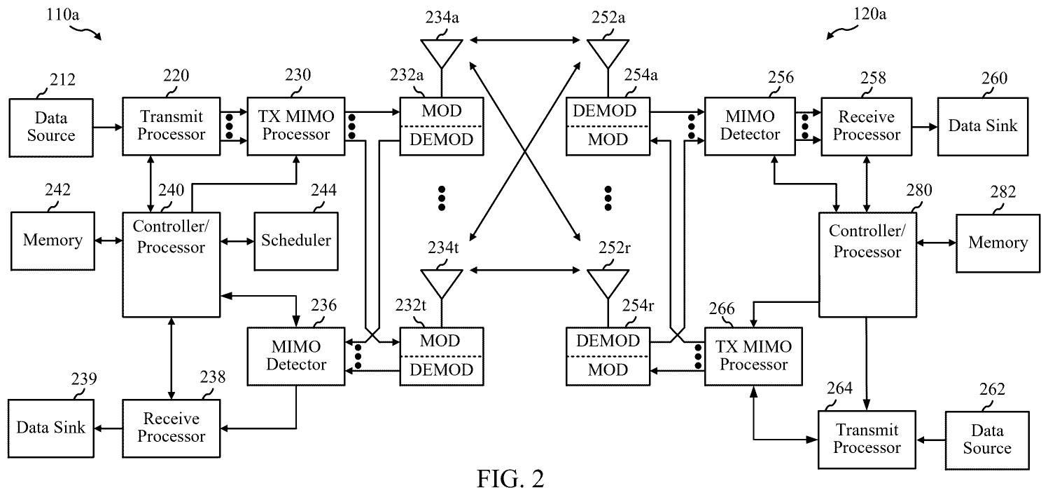

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

The transceivers 232a-232t and/or transceivers 254a-254r may be implemented with one or more amplifiers with OCP and OVP, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example Rf Transceiver

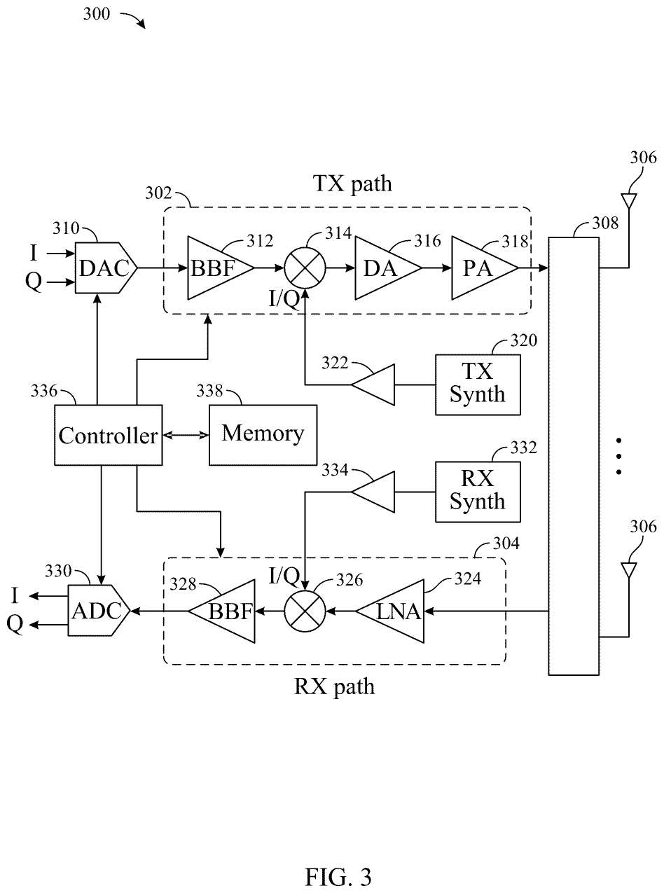

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies. ” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission. In some aspects, the DA 316 and/or PA 318 may be implemented with OCP and OVP, as described in more detail herein.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for any of various other suitable systems.

### Example Techniques for Over-voltage and Over-current Protection

Certain aspects of the present disclosure are directed towards over-voltage and over-current protection techniques. Under high mismatch or stress conditions, one or more radio frequency front end (RFFE) components, such as a power amplifier (PA) or filter (e.g., the PA 318 or a filter in the interface 308 of FIG. 3), may be damaged. The damage may be caused by high power dissipation (e.g., at high current and high voltage), even though the RFFE may not be operating at peak current or peak voltage. Therefore, protecting the RFFE component with only over-current or over-voltage protection may be difficult.

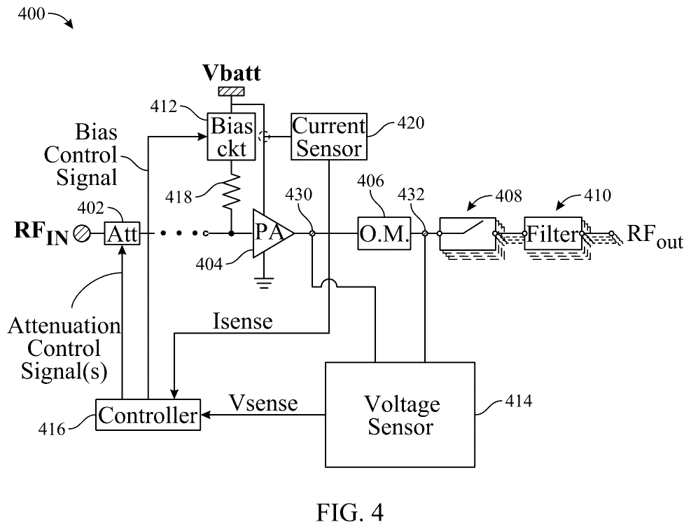

FIG. 4 illustrates an example RFFE 400 implemented with voltage and current sensing, in accordance with certain aspects of the present disclosure. As shown, the RFFE 400 may include a PA 404 (e.g., analogous to PA 318 of FIG. 3) having an input coupled to an RF input (labeled “RF_{IN}”). The input of the PA 404 may be coupled to the RF input through an attenuator 402. In some aspects, a bias circuit 412 may be coupled to the input of the PA 404 or at another location within the circuitry of the PA 404 (e.g., through a resistive element 418) and used to provide a bias current for operation of the PA 404.

The PA 404 may be supplied power from a power source, such as a voltage derived from a battery providing a battery voltage (Vbatt). The output of the PA 404 may be coupled to an output matching circuit 406 (labeled “O. M. ”) for impedance matching between the output of the PA and one or more subsequent components. The output matching circuit 406 may be selectively coupled to respective filters 410 via respective switches 408 for operation across different bands. The filters 410 may be coupled to one or more RF outputs labeled “RF_{OUT}”).

In some aspects of the present disclosure, the RFFE 400 may include a current sensor 420 that may sense an amount of current consumption of the PA 404 from the power source (e.g., from the battery providing Vbatt) and provide a current sense indication (Isense) to a controller 416 for over-current protection (OCP), for example. While the current sensor 420 is sensing the amount of current consumption of the PA 404 from the power source, some aspects of the present disclosure may be implemented by sensing any suitable current associated with the PA, such as an output current of the PA. In some aspects, the RFFE 400 may also include a voltage sensor 414 that may sense an output voltage of the PA 404, either at a PA output node 430 or at an output 432 of the matching circuit 406. The voltage sensor 414 may provide a voltage sense indication (Vsense) to the controller 416. Based on Isense and Vsense, the controller 416 may perform OCP and/or OVP based on one or more voltage and/or current thresholds relative to Isense and Vsense. For example, the controller 416 may adjust an overall gain to be applied to an input signal by adjusting the amount of attenuation of the input signal provided to the PA 404. Adjusting the amount of input signal attenuation may be accomplished by configuring one or more switches of the attenuator 402 via one or more attenuation control signals provided to at least one control input of the attenuator 402 and/or by adjusting the bias current provided by the bias circuit 412 for the PA 404 via a bias control signal provided to a control input of the bias circuit 412. The coupling between the attenuator 402 and the PA 404 may include one or more intervening components such as a DA (e.g., DA 316 of FIG. 3).

In some cases, voltage and current thresholds may be set sufficiently high to provide normal operations under low-stress conditions (e.g., with a voltage standing wave ratio (VSWR) of 2:1). That is, under low-stress conditions, the thresholds for OCP and OVP may be set high enough to allow the PA to generate signals that span voltage and current ranges per specifications. Thus, with the high thresholds, individual OVP and OCP may be insufficient to protect the RFFE components (e.g., PA 404 or one or more of the filters 410) during high-stress conditions, as described in more detail herein.

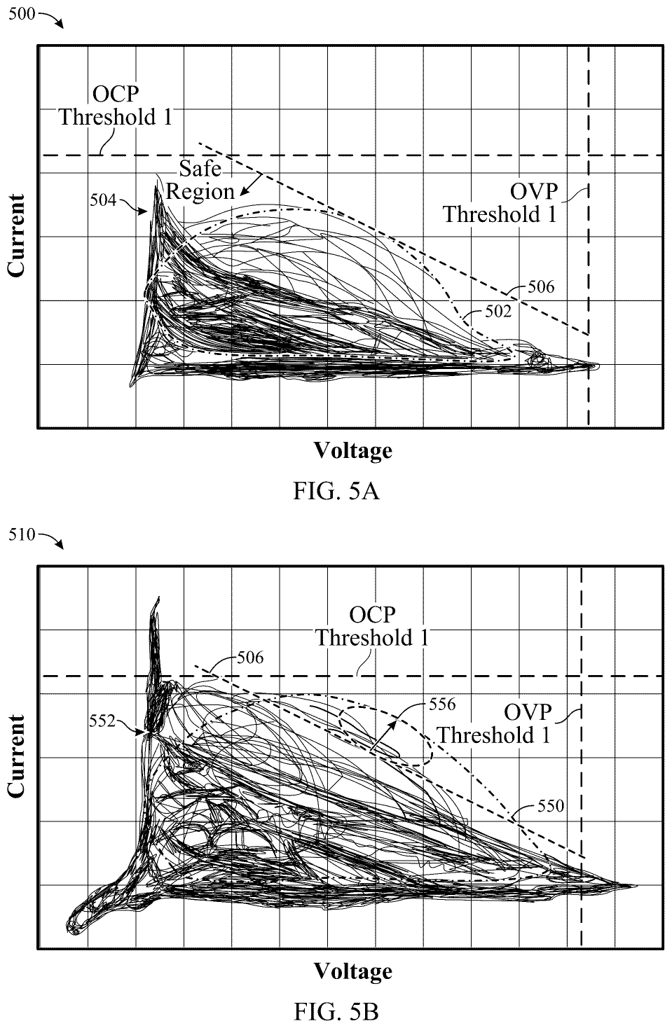

FIG. 5A is a graph 500 illustrating voltage and current consumption of a PA during low-stress conditions (e.g., VSWR of 2:1), in accordance with certain aspects of the present disclosure. The curve 502 shows a typical current and voltage characteristic of the PA during low-stress conditions, and the curves 504 show actual current and voltage consumptions of the PA during low-stress conditions. As shown, to allow for operations during low-stress conditions, an OCP threshold (e.g., labeled “OCP Threshold 1”) may be set at a current greater than the maximum current associated with curves 504, and an OVP threshold (e.g., labeled “OVP Threshold 1”) may be set to be greater than the maximum voltage associated with curves 504. The area under the line 506 indicates the safe operating region of the PA. If the sensed voltage or current is greater than the voltage or current represented by line 506, one or more RFFE components may be damaged. During low-stress conditions, the current and voltage associated with the PA may be within the safe operating region, under line 506.

FIG. 5B is a graph 510 illustrating voltage and current consumption of a PA during high-stress conditions (e.g., VSWR of 6:1), in accordance with certain aspects of the present disclosure. The curve 550 shows a typical current and voltage characteristic of the PA during high-stress conditions, and the curves 552 show actual current and voltage consumptions of the PA during high-stress conditions. As shown, the typical current and voltage characteristic of the PA during high-stress conditions involves currents and voltages that are greater than the maximum safe operating current and voltages represented by line 506, which may cause damage to RFFE components. There is a region of operation 556 where OCP or OVP is not triggered, but the PA is beyond the safe operating region. OCP and OVP operated individually may not protect the RFFE components from failure under high-stress conditions.

Certain aspects of the present disclosure are directed toward techniques that involve a combination of OCP and OVP for RFFE protection. For example, one or more current sensors may sense one or more currents associated with the PA, and one or more voltage sensors may sense one or more voltage associated the PA. Operating conditions of the PA may be adjusted based on a combination of the one or more sensed currents and the one or more sensed voltages. In this manner, lower thresholds that trigger OCP and OVP may be used with AND logic, for example, to protect the RFFE components, as described in more detail herein.

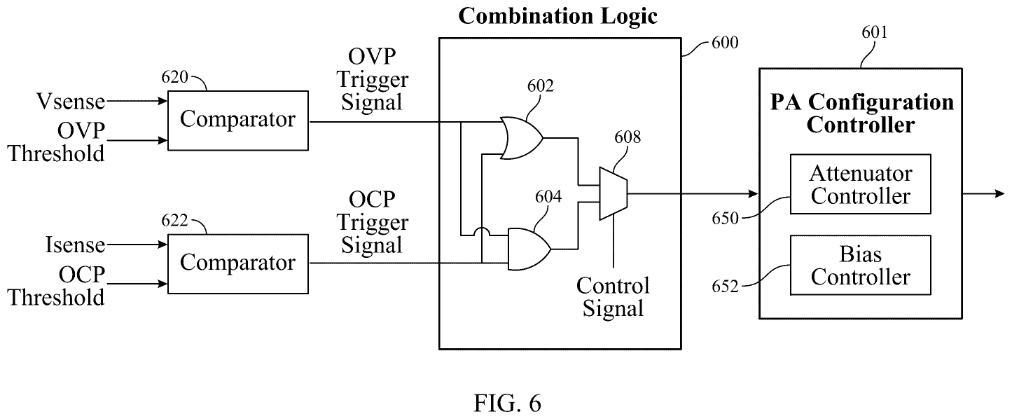

FIG. 6 illustrates combination logic 600 and PA configuration controller 601, in accordance with certain aspects of the present disclosure. The combination logic 600 and the PA configuration controller 601 may be part of the controller 416. A comparator 620 may receive Vsense (e.g., a voltage sensed via voltage sensor 414), which may be compared to an OVP threshold. If Vsense is equal to or greater than the OVP threshold, an OVP trigger signal at the output of the comparator 620 may transition from logic low to logic high. Similarly, a comparator 622 may receive Isense (e.g., a current sensed via current sensor 420), which may be compared to an OCP threshold. If Isense meets the OCP threshold, an OCP trigger signal at the output of the comparator 622 may transition from logic low to logic high. One or more comparators may be referred to herein as “comparator circuitry. ”

As shown, the OVP and OCP trigger signals may be provided to inputs of an AND gate 604 (also referred to as an “AND logic circuit”) and inputs of an OR gate 602 (e.g., also referred to as an “OR logic circuit”). The outputs of the AND gate 604 and the OR gate 602 may be provided to inputs of a multiplexer 608. The multiplexer 608 may receive a control signal and, based on the control signal, select whether to provide the output signal (e.g., referred to herein as an “over-power trigger signal”) of the AND gate 602 or the output signal of the OR gate 604 to the output of the combination logic 600. The output of the multiplexer 608 may be provided to the PA configuration controller 601 to adjust either the bias current and/or attenuation associated with the PA. In other words, by controlling the multiplexer 608, the PA configuration controller 601 may adjust the PA configuration (e.g., input signal attenuation or bias current to PA) based on an OR operation on the OVP and OCP trigger signals or an AND operation on the OVP and OCP trigger signals. For example, if using the AND operation, the PA configuration may either increase the attenuation of the input signal to the PA via an attenuation controller 650 and/or decrease the bias signal provided to the PA if both the OVP and OCP trigger signals are logic high indicating an over-power condition via a bias controller 652. In some cases, the combination logic may receive multiple OCP trigger signals associated with different OCP thresholds and multiple OVP trigger signals associated with different OVP thresholds, based on which the PA configuration controller 601 may adjust the PA configuration, as described in more detail herein.

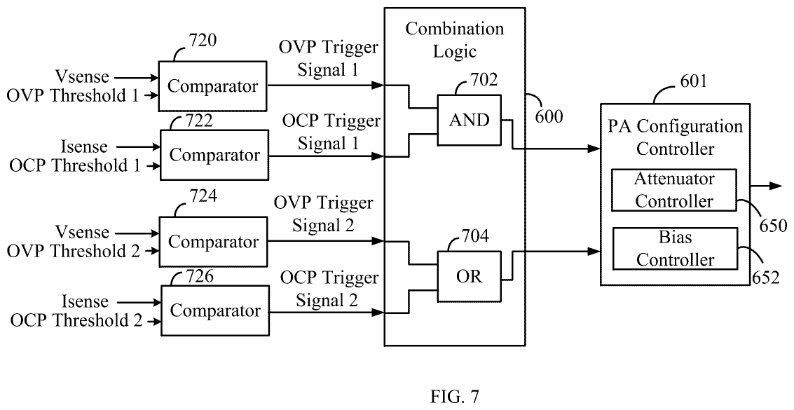

FIG. 7 illustrates the combination logic 600 processing multiple OCP trigger signals associated with different OCP thresholds and multiple OVP trigger signals associated with different OVP threshold, in accordance with certain aspects of the present disclosure. As shown, a comparator 720 (that may be external to or included in the controller 416) may receive Vsense (e.g., a voltage sensed via voltage sensor 414), which may be compared to a first OVP threshold (OVP threshold 1). If Vsense is equal to or greater than OVP threshold 1, a first OVP trigger signal (OVP trigger signal 1) at the output of the comparator 720 may transition from logic low to logic high. Similarly, a comparator 722 may receive Isense (e.g., a current sensed via current sensor 420), which may be compared to a first OCP threshold (OCP threshold 1). If Isense is equal to or greater than OCP threshold 1, a first OCP trigger signal (OCP trigger signal 1) at the output of the comparator 722 may transition from logic low to logic high. The combination logic 600 may include an AND gate 702 that may perform an AND operation on the OVP trigger signal 1 and the OCP trigger signal 1 to generate an over-power trigger signal that may be provided to the PA configuration controller 601 for adjusting the attenuation of the input signal to the PA and/or the bias current of the PA if an over-power condition occurs (e.g., if both over-voltage and over-current conditions arise), as described herein.

A comparator 724 (that may be external to or included in the controller 416) may receive Vsense (e.g., a voltage sensed via voltage sensor 414), which may be compared to a second OVP threshold (OVP threshold 2). OVP threshold 2 may be greater than OVP threshold 1. If Vsense is equal to or greater than OVP threshold 2, a second OVP trigger signal (OVP trigger signal 2) at the output of the comparator 724 may transition from logic low to logic high. Similarly, a comparator 726 may receive Isense (e.g., a current sensed via current sensor 420), which may be compared to a second OCP threshold (OCP threshold 2). OCP threshold 2 may be greater than OCP threshold 1. If Isense meets OCP threshold 2, a second OCP trigger signal (OCP trigger signal 2) at the output of the comparator 726 may transition from logic low to logic high. The combination logic 600 may include an OR gate 704 that may perform an OR operation on the OVP trigger signal 2 and the OCP trigger signal 2 to generate an over-voltage or current trigger signal that may be provided to the PA configuration controller 601 for adjusting the attenuation of the input signal to the PA and/or the bias current of the PA if an over-voltage or over-current condition occurs, as described herein.

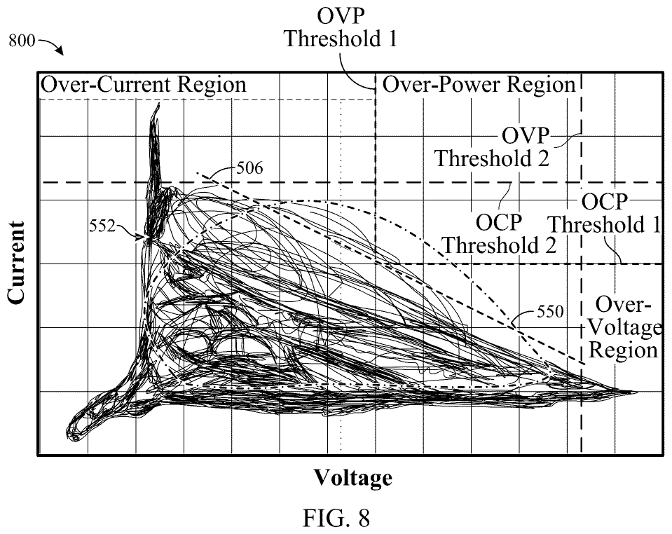

FIG. 8 is a graph 800 illustrating voltage and current consumption of a PA during high-stress conditions with over-power protection, in accordance with certain aspects of the present disclosure. With the combination logic performing an AND operation on OCP and OVP trigger signals, lower thresholds (e.g., OVP threshold 1 and OCP threshold 1) may be used to provide protection for high-stress conditions, where OCP and OVP trigger signals associated with higher thresholds (e.g., OVP threshold 2 and OCP threshold 2) may be used for protection during low-stress conditions. For example, the OR operation of OCP trigger signal 2 and OVP trigger signal 2 via the OR gate 704 of FIG. 7 may be used to provide OCP and OVP during low-stress conditions as described with respect to FIG. 5A. The AND operation via AND gate 702 of OCP trigger signal 1 and OVP trigger signal 1 may be used to provide OCP and OVP during high-stress conditions. That is, as shown in graph 800, the PA configuration controller may increase the attenuation of the input signal of the PA and/or decrease the bias current to the PA to protect the RFFE if the PA is operating within the over-power region (e.g., if both the OCP trigger signal 1 and OVP trigger signal 1 are triggered as indicated at the output of AND gate 702). For low-stress conditions, the PA configuration controller 601 may increase the attenuation of the input signal of the PA and/or decrease the bias current to the PA to protect the RFFE if the PA is operating within the over-voltage or current region (e.g., if the OCP trigger signal 1 or OVP trigger signal 1 are triggered as indicated at the output of OR gate 704).

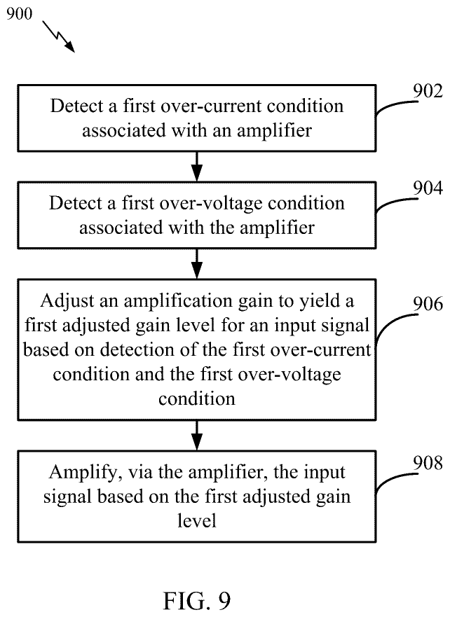

FIG. 9 is a flow diagram illustrating example operations 900 for signal amplification, in accordance with certain aspects of the present disclosure. The operations 900 may be performed, for example, by an RFFE, such as the RFFE 400 of FIG. 4, by a controller, such as the controller 416, and/or by comparator circuitry, such as the comparators 720, 722, 724, 726 of FIG. 7.

At block 902, the controller may detect a first over-current condition associated with an amplifier (e.g., PA 404 of RFFE 400). At block 904, the controller may detect a first over-voltage condition associated with the amplifier.

At block 906, the controller may adjust an amplification gain to yield a first adjusted gain level for an input signal based on detection of the first over-current condition and the first over-voltage condition. At block 908, the RFFE may amplify, via the amplifier, the input signal based on the first adjusted gain level.

In some aspects, adjusting the amplification gain may include adjusting a level of attenuation associated with an attenuator (e.g., attenuator 402 of RFFE 400) coupled to an input of the amplifier. Additionally or alternatively, adjusting the amplification gain may include adjusting a bias current (e.g., generated via bias circuit 412) for the amplifier.

In some aspects, the controller or the comparator circuitry may generate an over-current trigger signal based on detection of the first over-current condition, and generate an over-voltage trigger signal based on detection of the first over-voltage condition. The controller may perform an AND operation (e.g., via AND gate 704) on the over-current trigger signal and the over-voltage trigger signal to yield an over-power trigger signal, the amplification gain being adjusted based on the over-power trigger signal.

In some aspects, to detect the first over-current condition, the controller may compare (e.g., via comparator 722 of FIG. 7) a sensed current associated with the amplifier with a first current threshold. To detect the first over-voltage condition, the controller may compare (e.g., via comparator 720 of FIG. 7) a sensed voltage associated with the amplifier with a first voltage threshold.

In some aspects, the controller or the comparator circuitry may detect a second over-current condition associated with the amplifier and detect a second over-voltage condition associated with the amplifier. The controller may adjust the amplification gain to yield a second adjusted gain level for the input signal based on detection of the second over-current condition or the second over-voltage condition. The RFFE may amplify, via the amplifier (e.g., PA 404), the input signal based on the second adjusted gain level.

In some aspects, detecting the first over-current condition may include comparing (e.g., via comparator 722 of FIG. 7) a first sensed current associated with the amplifier with a first current threshold (e.g., OCP threshold 1) and detecting the first over-voltage condition may include comparing (e.g., via comparator 720) a first sensed voltage associated with the amplifier with a first voltage threshold (e.g., OVP threshold 1). In some aspects, detecting the second over-current condition may include comparing (e.g., via comparator 726) a second sensed current associated with the amplifier with a second current threshold (e.g., OCP threshold 2) different than the first current threshold, and detecting the second over-voltage condition may include comparing (e.g., via comparator 724) a second sensed voltage associated with the amplifier with a second voltage threshold (e.g., OVP threshold 2) different than the first voltage threshold. The first current threshold may be less than the second current threshold, and the first voltage threshold may be less than the second voltage threshold.

In some aspects, the controller or the comparator circuitry may generate an over-current trigger signal based on detection of the second over-current condition and generate an over-voltage trigger signal based on detection of the second over-voltage condition. The controller may perform an OR operation (e.g., via OR gate 704) on the over-current trigger signal and the over-voltage trigger signal to yield an over-current or voltage trigger signal, the amplification gain being adjusted to yield the second adjusted gain level based on the over-current or voltage trigger signal. In some aspects, the controller may select (e.g., via multiplexer 608) to perform the adjustment of the amplification gain based on: detection of both the first over-current condition and the first over-voltage condition; or detection of one of the first over-current condition and the first over-voltage condition, wherein the amplification gain is adjusted based on the selection.

### EXAMPLE ASPECTS

In addition to the various aspects described above, specific combinations of aspects are within the scope of the present disclosure, some of which are detailed below:

### Aspect 1

An apparatus for signal amplification, comprising: a current sensor configured to sense a current associated with an amplifier; a voltage sensor configured to sense a voltage associated with the amplifier; and a logic circuit configured to: detect a first over-current condition associated with the amplifier based on the current; detect a first over-voltage condition associated with the amplifier based on the voltage; and adjust an amplification gain to yield a first adjusted gain level for an input signal based on detection of the first over-current condition and the first over-voltage condition, wherein the amplifier is configured to amplify the input signal based on the first adjusted gain level.

### Aspect 2

The apparatus of Aspect 1, further comprising an attenuator coupled to an input of the amplifier, wherein, to adjust the amplification gain, the logic circuit is configured to adjust a level of attenuation associated with the attenuator.

### Aspect 3

The apparatus of Aspect 1 or 2, further comprising a bias circuit configured to generate a bias current for the amplifier, wherein, to adjust the amplification gain, the logic circuit is configured to adjust the bias current for the amplifier.

### Aspect 4

The apparatus according to any of Aspects 1-3, wherein the logic circuit comprises: comparator circuitry configured to: generate an over-current trigger signal based on detection of the first over-current condition; and generate an over-voltage trigger signal based on detection of the first over-voltage condition; and an AND gate configured to perform an AND operation on the over-current trigger signal and the over-voltage trigger signal to yield an over-power trigger signal, wherein the logic circuit is configured to adjust the amplification gain based on the over-power trigger signal.

### Aspect 5

The apparatus according to any of Aspects 1-4, wherein the logic circuit comprises comparator circuitry configured to: compare the sensed current associated with the amplifier with a first current threshold to detect the first over-current condition; and compare the sensed voltage associated with the amplifier with a first voltage threshold to detect the first over-voltage condition comprises.

### Aspect 6

The apparatus according to any of Aspects 1-5, wherein: the logic circuit further comprises comparator circuitry configured to: detect a second over-current condition associated with the amplifier; and detect a second over-voltage condition associated with the amplifier; the logic circuit is configured to adjust the amplification gain to yield a second adjusted gain level for the input signal based on detection of the second over-current condition or the second over-voltage condition; and the amplifier is configured to amplify the input signal based on the second adjusted gain level.

### Aspect 7

The apparatus of Aspect 6, wherein the comparator circuitry is further configured to: compare a sensed current associated with the amplifier with a first current threshold to detect the first over-current condition; compare a sensed voltage associated with the amplifier with a first voltage threshold to detect the first over-voltage condition; compare the sensed current associated with the amplifier with a second current threshold different than the first current threshold to detect the second over-current condition; and compare the sensed voltage associated with the amplifier with a second voltage threshold different than the first voltage threshold to detect the second over-voltage condition.

### Aspect 8

The apparatus of Aspect 7, wherein the first current threshold is less than the second current threshold, and wherein the first voltage threshold is less than the second voltage threshold.

### Aspect 9

The apparatus of Aspect 7 or 8, wherein: the comparator circuitry is configured to: generate an over-current trigger signal based on detection of the second over-current condition; and generate an over-voltage trigger signal based on detection of the second over-voltage condition; and the logic circuit further comprises an OR gate configured to perform an OR operation on the over-current trigger signal and the over-voltage trigger signal to yield an over-current or over-voltage trigger signal, the amplification gain being adjusted to yield the second adjusted gain level based on the over-current or over-voltage trigger signal.

### Aspect 10

The apparatus according to any of Aspects 1-9, wherein the logic circuit further comprises a multiplexer configured to select between performing the adjustment of the amplification gain based on: detection of both the first over-current condition and the first over-voltage condition; or detection of one of the first over-current condition and the first over-voltage condition, wherein the amplification gain is adjusted based on the selection.

### Aspect 11

An apparatus for signal amplification, comprising: an amplifier; a current sensor coupled to the amplifier; a voltage sensor coupled to the amplifier; a first comparator having an input coupled to an output of the current sensor; a second comparator having an input coupled to an output of the voltage sensor; an AND gate having inputs coupled to outputs of the first comparator and the second comparator; and a controller having an input coupled to an output of the AND gate and an output coupled to a circuit associated with the amplifier.

### Aspect 12

The apparatus of Aspect 11, wherein the controller is configured to adjust a gain level of the amplifier based on an output signal of the AND logic circuit.

### Aspect 13

The apparatus of Aspect 11, further comprising an attenuator coupled to an input of the amplifier, wherein the output of the controller is coupled to a control input of the attenuator.

### Aspect 14

The apparatus of Aspect 11, 12, or 13, further comprising a bias circuit coupled to the amplifier, wherein the output of the controller is coupled to a control input of the bias circuit.

### Aspect 15

The apparatus according to any of Aspects 11-14, further comprising: an OR gate including inputs coupled to outputs of the first comparator and the second comparator; and a multiplexer including inputs coupled to an output of the OR gate and the output of the AND gate and an output coupled to the input of the controller.

### Aspect 16

The apparatus according to any of Aspects 11-15, further comprising: a third comparator having an input coupled to the output of the current sensor; a fourth comparator having an input coupled to the output of the voltage sensor; and an OR gate having inputs coupled to outputs of the third comparator and the fourth comparator, wherein the controller includes another input coupled to an output of the OR gate.

### Aspect 17

A method for signal amplification, comprising: detecting a first over-current condition associated with an amplifier; detecting a first over-voltage condition associated with the amplifier; adjusting an amplification gain to yield a first adjusted gain level for an input signal based on the detection of the first over-current condition and the first over-voltage condition; and amplifying, via the amplifier, the input signal based on the first adjusted gain level.

### Aspect 18

The method of Aspect 17, wherein adjusting the amplification gain comprises adjusting a level of attenuation associated with an attenuator coupled to an input of the amplifier.

### Aspect 19

The method of Aspect 17 or 18, wherein adjusting the amplification gain comprises adjusting a bias current for the amplifier.

### Aspect 20

The method according to any of Aspects 17-19, further comprising: generating an over-current trigger signal based on the detection of the first over-current condition; generating an over-voltage trigger signal based on the detection of the first over-voltage condition; and performing an AND operation on the over-current trigger signal and the over-voltage trigger signal to yield an over-power trigger signal, the amplification gain being adjusted based on the over-power trigger signal.

### Aspect 21

The method according to any of Aspects 17-20, wherein: detecting the first over-current condition comprises comparing a sensed current associated with the amplifier with a first current threshold; and detecting the first over-voltage condition comprises comparing a sensed voltage associated with the amplifier with a first voltage threshold.

### Aspect 22

The method according to any of Aspects 17-21, further comprising: detecting a second over-current condition associated with the amplifier; detecting a second over-voltage condition associated with the amplifier; adjusting the amplification gain to yield a second adjusted gain level for the input signal based on detection of the second over-current condition or the second over-voltage condition; and amplifying, via the amplifier, the input signal based on the second adjusted gain level.

### Aspect 23

The method of Aspect 22, wherein: detecting the first over-current condition comprises comparing a sensed current associated with the amplifier with a first current threshold; detecting the first over-voltage condition comprises comparing a sensed voltage associated with the amplifier with a first voltage threshold; detecting the second over-current condition comprises comparing the sensed current associated with the amplifier with a second current threshold different than the first current threshold; and detecting the second over-voltage condition comprises comparing the sensed voltage associated with the amplifier with a second voltage threshold different than the first voltage threshold.

### Aspect 24

The method of Aspect 23, wherein the first current threshold is less than the second current threshold, and wherein the first voltage threshold is less than the second voltage threshold.

### Aspect 25

The method of Aspect 23 or 24, further comprising: generating an over-current trigger signal based on the detection of the second over-current condition; generating an over-voltage trigger signal based on the detection of the second over-voltage condition; and performing an OR operation on the over-current trigger signal and the over-voltage trigger signal to yield an over-current or over-voltage trigger signal, the amplification gain being adjusted to yield the second adjusted gain level based on the over-current or over-voltage trigger signal.

### Aspect 26

The method according to any of Aspects 17-25, further comprising selecting to perform the adjustment of the amplification gain based on: the detections of both the first over-current condition and the first over-voltage condition; or the detection of one of the first over-current condition and the first over-voltage condition, wherein the amplification gain is adjusted based on the selection.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An apparatus for signal amplification, comprising:
a current sensor configured to sense a current associated with an amplifier;
a voltage sensor configured to sense a voltage associated with the amplifier; and
a logic circuit configured to:
detect a first over-current condition associated with the amplifier based on the current;
detect a first over-voltage condition associated with the amplifier based on the voltage; and
adjust an amplification gain to yield a first adjusted gain level for an input signal based on detection of the first over-current condition and the first over-voltage condition, wherein the amplifier is configured to amplify the input signal based on the first adjusted gain level.

2. The apparatus of claim 1, further comprising an attenuator coupled to an input of the amplifier, wherein, to adjust the amplification gain, the logic circuit is configured to adjust a level of attenuation associated with the attenuator.

3. The apparatus of claim 1, further comprising a bias circuit configured to generate a bias current for the amplifier, wherein, to adjust the amplification gain, the logic circuit is configured to adjust the bias current for the amplifier.

4. The apparatus of claim 1, wherein the logic circuit comprises:
comparator circuitry configured to:
generate an over-current trigger signal based on detection of the first over-current condition; and
generate an over-voltage trigger signal based on detection of the first over-voltage condition; and
an AND logic circuit configured to perform an AND operation on the over-current trigger signal and the over-voltage trigger signal to yield an over-power trigger signal, wherein the logic circuit is configured to adjust the amplification gain based on the over-power trigger signal.

5. The apparatus of claim 1, wherein the logic circuit comprises comparator circuitry configured to:
compare the sensed current associated with the amplifier with a first current threshold to detect the first over-current condition; and
compare the sensed voltage associated with the amplifier with a first voltage threshold to detect the first over-voltage condition comprises.

6. The apparatus of claim 1, wherein:
the logic circuit further comprises comparator circuitry configured to:
detect a second over-current condition associated with the amplifier; and
detect a second over-voltage condition associated with the amplifier;
the logic circuit is configured to adjust the amplification gain to yield a second adjusted gain level for the input signal based on detection of the second over-current condition or the second over-voltage condition; and
the amplifier is configured to amplify the input signal based on the second adjusted gain level.

7. The apparatus of claim 6, wherein the comparator circuitry is further configured to:
compare a sensed current associated with the amplifier with a first current threshold to detect the first over-current condition;
compare a sensed voltage associated with the amplifier with a first voltage threshold to detect the first over-voltage condition;
compare the sensed current associated with the amplifier with a second current threshold different than the first current threshold to detect the second over-current condition; and
compare the sensed voltage associated with the amplifier with a second voltage threshold different than the first voltage threshold to detect the second over-voltage condition.

8. The apparatus of claim 7, wherein the first current threshold is less than the second current threshold, and wherein the first voltage threshold is less than the second voltage threshold.

9. The apparatus of claim 7, wherein:
the comparator circuitry is configured to:
generate an over-current trigger signal based on detection of the second over-current condition; and
generate an over-voltage trigger signal based on detection of the second over-voltage condition; and
the logic circuit further comprises an OR logic circuit configured to perform an OR operation on the over-current trigger signal and the over-voltage trigger signal to yield an over-current or over-voltage trigger signal, the amplification gain being adjusted to yield the second adjusted gain level based on the over-current or over-voltage trigger signal.

10. The apparatus of claim 1, wherein the logic circuit further comprises a multiplexer configured to select between performing the adjustment of the amplification gain based on:
detection of both the first over-current condition and the first over-voltage condition; or
detection of one of the first over-current condition and the first over-voltage condition, wherein the amplification gain is adjusted based on the selection.

11. An apparatus for signal amplification, comprising:
an amplifier;
a current sensor coupled to the amplifier;
a voltage sensor coupled to the amplifier;
a first comparator having an input coupled to an output of the current sensor;
a second comparator having an input coupled to an output of the voltage sensor;
an AND logic circuit having inputs coupled to outputs of the first comparator and the second comparator; and
a controller having an input coupled to an output of the AND logic circuit and an output coupled to a circuit associated with the amplifier.

12. The apparatus of claim 1, wherein the controller is configured to adjust a gain level of the amplifier based on an output signal of the AND logic circuit.

13. The apparatus of claim 11, further comprising an attenuator coupled to an input of the amplifier, wherein the output of the controller is coupled to a control input of the attenuator.

14. The apparatus of claim 11, further comprising a bias circuit coupled to the amplifier, wherein the output of the controller is coupled to a control input of the bias circuit.

15. The apparatus of claim 11, further comprising:
an OR gate including inputs coupled to outputs of the first comparator and the second comparator; and
a multiplexer including inputs coupled to an output of the OR gate and the output of the AND logic circuit and an output coupled to the input of the controller.

16. The apparatus of claim 11, further comprising:
a third comparator having an input coupled to the output of the current sensor;
a fourth comparator having an input coupled to the output of the voltage sensor; and
an OR logic circuit having inputs coupled to outputs of the third comparator and the fourth comparator, wherein the controller includes another input coupled to an output of the OR logic circuit.

17. A method for signal amplification, comprising:
detecting a first over-current condition associated with an amplifier;
detecting a first over-voltage condition associated with the amplifier;
adjusting an amplification gain to yield a first adjusted gain level for an input signal based on the detection of the first over-current condition and the first over-voltage condition; and
amplifying, via the amplifier, the input signal based on the first adjusted gain level.

18. The method of claim 17, wherein adjusting the amplification gain comprises adjusting a level of attenuation associated with an attenuator coupled to an input of the amplifier.

19. The method of claim 17, wherein adjusting the amplification gain comprises adjusting a bias current for the amplifier.

20. The method of claim 17, further comprising:
generating an over-current trigger signal based on the detection of the first over-current condition;
generating an over-voltage trigger signal based on the detection of the first over-voltage condition; and
performing an AND operation on the over-current trigger signal and the over-voltage trigger signal to yield an over-power trigger signal, the amplification gain being adjusted based on the over-power trigger signal.
